(19) United States
(12) Patent Application Publication
(10) Pub. No.: US 2026/0336310 A1
(43) Pub. Date: Oct. 29, 2026

(54) PRINTING APPARATUS

(71) Applicant: CANON KABUSHIKI KAISHA, Tokyo (JP)

(72) Inventors: TSUTOMU OBATA, Tokyo (JP); RYOYA SHINJO, Kanagawa (JP); TOMOHIRO SUZUKI, Tokyo (JP)

(21) Appl. No.: 19/468,974

(22) Filed: Feb. 3, 2026

(30) Foreign Application Priority Data
Feb. 19, 2025 (JP) 2025-025040

(51) Int. Cl. B41J 11/00; B41J 15/04; B41J 15/16; H05K 5/00; B41J 2/01

(52) U.S. Cl. CPC B41J 11/0095; B41J 15/042; B41J 15/046; B41J 15/048; B41J 15/16; H05K 5/0017; B41J 2/01

(57) ABSTRACT

A printing apparatus includes a conveyance unit that conveys a sheet, a printing unit that prints an image on the conveyed sheet, a winding unit that moves between a first position where a user fixes a leading edge of the sheet and a second position where the sheet is wound, downstream of the printing unit in a sheet conveyance direction, a display unit that displays a first display prompting the user to fix the leading edge of the sheet to the winding unit and a second display prompting the user to move the winding unit from the first position to the second position, and a fixing detection unit that detects that the user fixes the leading edge of the sheet, wherein the display unit displays the second display in a case where the sheet is conveyed by a predetermined amount after detection by the fixing detection unit.

### BACKGROUND

### Field of the Technology

The present disclosure relates to a printing apparatus.

### Description of the Related Art

A winding device has been discussed that performs printing on a roll sheet and then winds the printed sheet into a roll. According to Japanese Patent Laid-Open No. 2016-97527, a winding device is described that displays an instruction on a display panel or the like, prompting a user to fix a leading edge of a sheet to a paper tube.

According to Japanese Patent Laid-Open No. 2016-97527, a user needs to fix the leading edge of the sheet to the paper tube located at the rear of the device, which results in poor workability. In order to improve the workability, it is conceivable to configure the paper tube so that it can be moved from the rear side to the front side of the device. However, if the leading edge of the sheet is fixed at the front side and the paper tube is then returned to the rear side, there is a concern that the sheet may become stretched and the leading edge thereof may peel off in some cases.

### SUMMARY

According to some embodiments of the present disclosure, a printing apparatus includes a conveyance unit configured to convey a sheet, a printing unit configured to print an image on the sheet conveyed by the conveyance unit, a winding unit configured to move between a first position where a user fixes a leading edge of the sheet and a second position where the sheet is wound, downstream of the printing unit in a sheet conveyance direction, a display unit configured to display a first display prompting the user to fix the leading edge of the sheet to the winding unit and a second display prompting the user to move the winding unit from the first position to the second position, and a fixing detection unit configured to detect that the user fixes the leading edge of the sheet, wherein the display unit displays the second display in a case where the sheet is conveyed by a predetermined amount from the conveyance unit after detection by the fixing detection unit.

Features of the present disclosure will become apparent from the following description of embodiments with reference to the attached drawings. The following description of embodiments is described by way of example.

### BRIEF DESCRIPTION OF THE DRAWINGS

FIG. 1 is a perspective view of a printing apparatus.

FIG. 2A illustrates the printing apparatus with a roll temporarily placed (a supply device is located above). FIG. 2B illustrates the printing apparatus with the roll set in a main body (the supply device is located above). FIG. 2C illustrates the printing apparatus with the roll temporarily placed (the supply device is located below). FIG. 2D illustrates the printing apparatus with the roll set in the main body (the supply device is located below).

FIG. 3 is an enlarged cross-sectional view of the supply device in FIG. 2A.

FIG. 4 is an enlarged cross-sectional view of the supply device in FIG. 2B.

FIG. 5A is a schematic top view of a sheet supply device before holding the roll, as seen from above in a Z direction. FIG. 5B is a schematic top view of the sheet supply device after holding the roll, as seen from above in the Z direction.

FIG. 6A illustrates a position of a sheet before it is set in a winding unit. FIG. 6B illustrates the position of the sheet if it is attached to a holding unit without slack during setting in the winding unit. FIG. 6C illustrates the position of the sheet if it is attached to the holding unit with slack during setting in the winding unit. FIG. 6D illustrates the sheet set in the main body by rotating the holding unit from the state illustrated in FIG. 6C.

FIG. 7 is a block diagram illustrating a control system of the printing apparatus.

FIG. 8 is a flowchart illustrating sheet conveyance control in performing winding and setting before a printing operation.

FIG. 9 is a flowchart illustrating sheet conveyance control in performing winding and setting during a printing operation.

FIGS. 10A-10D illustrate examples of displays on a display panel.

FIGS. 11A and 11B illustrate examples of displays on the display panel.

FIG. 12 is an enlarged cross-sectional view of a winding device illustrated in FIG. 2A.

FIG. 13 is an enlarged cross-sectional view of the winding device illustrated in FIG. 2A.

FIG. 14A is a schematic top view of the winding device before holding the roll, as seen from above in the Z direction. FIG. 14B is a schematic top view of the winding device after holding the roll, as seen from above in the Z direction.

### DESCRIPTION OF THE EMBODIMENTS

Various exemplary embodiments, features, and aspects of a printing apparatus and a control method will be described in detail below with reference to the attached drawings. The following embodiments are not intended to limit the present disclosure, and not all combinations of features described in the embodiments are necessarily essential to the solutions according to the present disclosure. The relative positions, shapes, and the like of the components described in the embodiments are merely examples and are not intended to limit the scope of the present disclosure to them.

### First Embodiment

### Basic Configuration

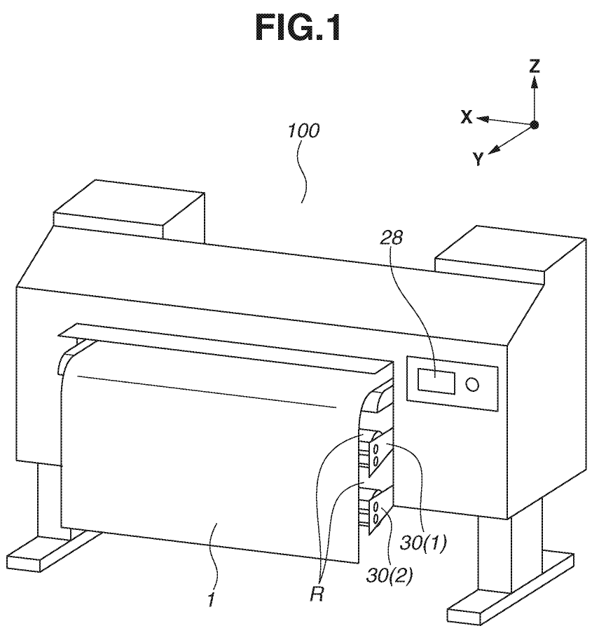

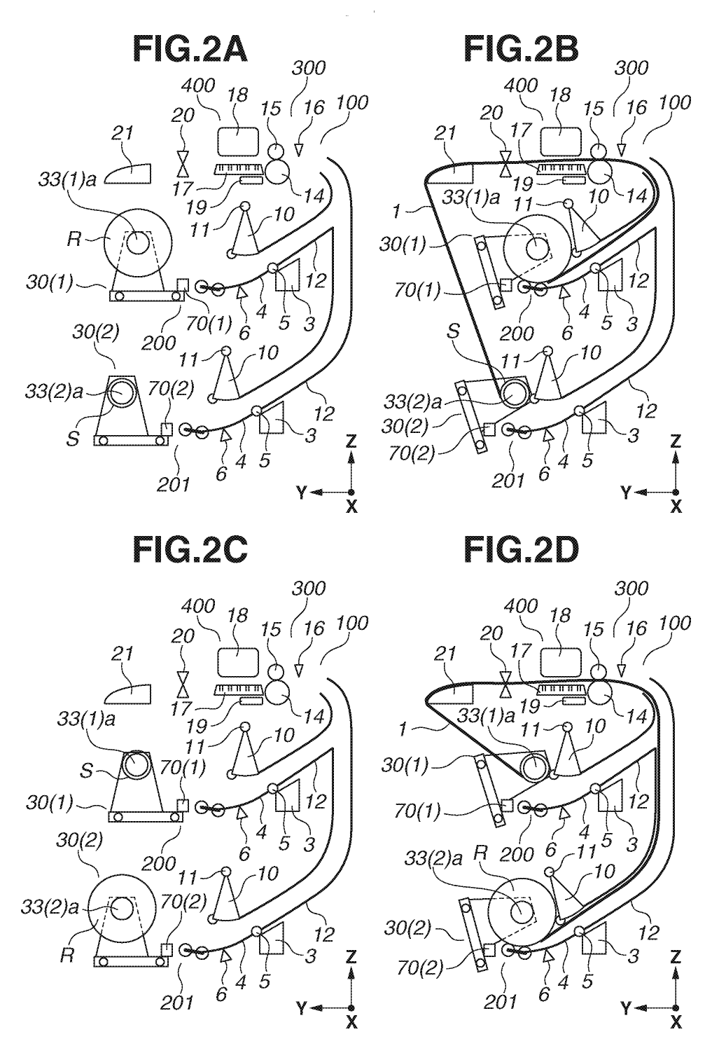

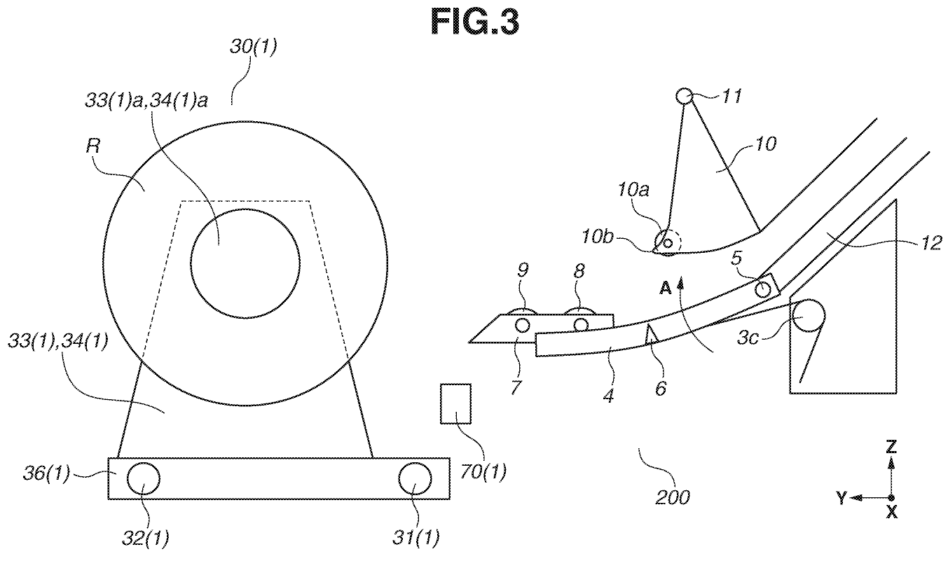

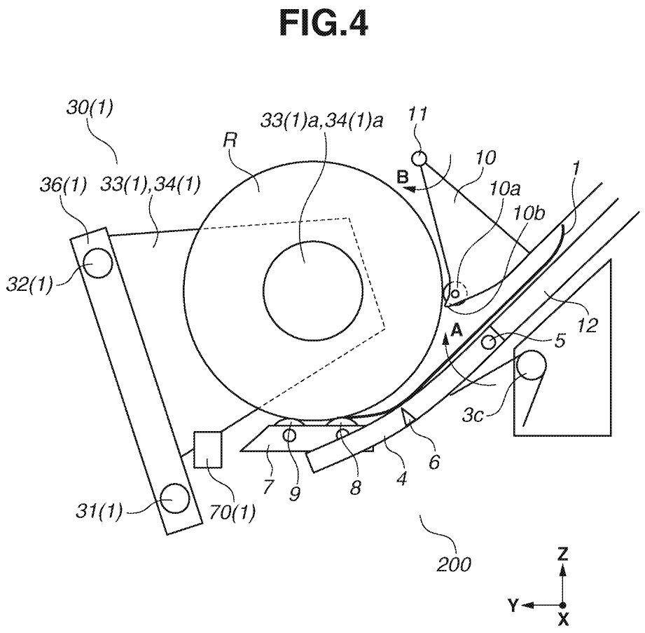

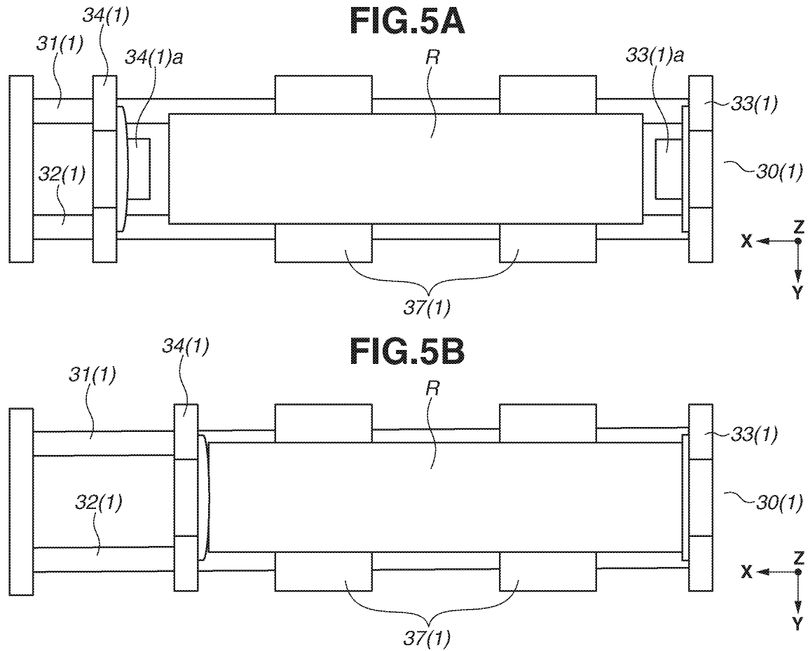

FIGS. 1-5A and 5B illustrate a basic configuration of a printing apparatus as an application example of the present disclosure. FIG. 1 is a perspective view of a printing apparatus 100 (also referred to as the apparatus). FIGS. 2A-2D are schematic cross-sectional views of main parts of the printing apparatus 100. FIGS. 3 and 4 are enlarged cross-sectional views of a supply/winding device 200. FIGS. 5A and 5B are schematic top views of the supply/winding device 200 as seen from above in the Z direction.

FIG. 1 illustrates the printing apparatus 100 according to the present embodiment. A roll (roll sheet) R, in which a long continuous sheet 1 is wound into a roll form, can be set in each of two holding units 30(1) and 30(2) located in upper and lower sections. A display panel 28 serves as both a display unit, such as a liquid crystal display (LCD), capable of displaying information and a touch sensor that receives a user operation. An operation member of the display panel 28 that receives the user operation may be a switch or the like instead of the touch sensor.

The sheet 1 from the roll R set in the holding unit 30(1) or 30(2) is printed in an apparatus main body, and the printed sheet is discharged to a front side of the apparatus main body. The discharged sheet is cut by a cutter in the apparatus main body and stored in a basket (not illustrated).

For the sake of explanation, coordinate axes are set as illustrated in the drawings. Specifically, a sheet width direction of the roll R is defined as an X-axis direction, a direction in which the sheet 1 is conveyed in a printing unit 400, which is described below, is defined as a Y-axis direction, and the direction of gravity is defined as a Z-axis direction.

FIGS. 2A-2D are schematic side views of the printing apparatus 100, illustrating a case where one of the holding units 30(1) and 30(2) is used as a supply device that supplies the sheet 1 and the other is used as a winding device that winds the sheet 1.

As illustrated in FIGS. 2A-2D, the supply/winding devices 200 and 201 function as supply units that supply the sheet 1. Similarly, the supply/winding devices 200 and 201 also function as winding units that wind up the sheet 1.

Hereinbelow, in a case where the supply/winding devices 200 and 201 function as supply units, they are referred to as the supply devices 200 and 201, and in a case where they function as winding units, they are referred to as the winding devices 200 and 201.

In a direction in which the sheet 1 is conveyed in the printing apparatus 100, the supply unit that supplies the sheet 1 is described as being on the upstream side of a sheet conveyance direction, and the winding unit that winds the sheet 1 is described as being on the downstream side of the sheet conveyance direction.

FIGS. 2A and 2B are schematic cross-sectional views illustrating a case where the supply device 200 on which the roll R is mounted serves as the supply unit that supplies the sheet 1, and the winding device 201 on which a winding core S is mounted serves as the winding unit that winds the sheet 1. FIGS. 2C and 2D are schematic cross-sectional views illustrating a case where the winding device 201 on which the roll R is mounted serves as the supply unit that supplies the sheet 1, and the winding device 200 on which the winding core S is mounted serves as the winding unit that winds the sheet 1. As illustrated in FIGS. 2A-2D, the functions of both the supply unit and the winding unit can be assigned to either the upper or lower section. The display panel 28 described with reference to FIG. 1 can be used to input various commands to the printing apparatus 100, such as specifying a size of the sheet 1, setting whether the supply/winding devices 200 and 201 are used as the supply unit or the winding unit, and the like. A central processing unit (CPU) 220 can detect an operation from a user based on the input signal. The display panel 28 can also display a message prompting the user to perform an operation.

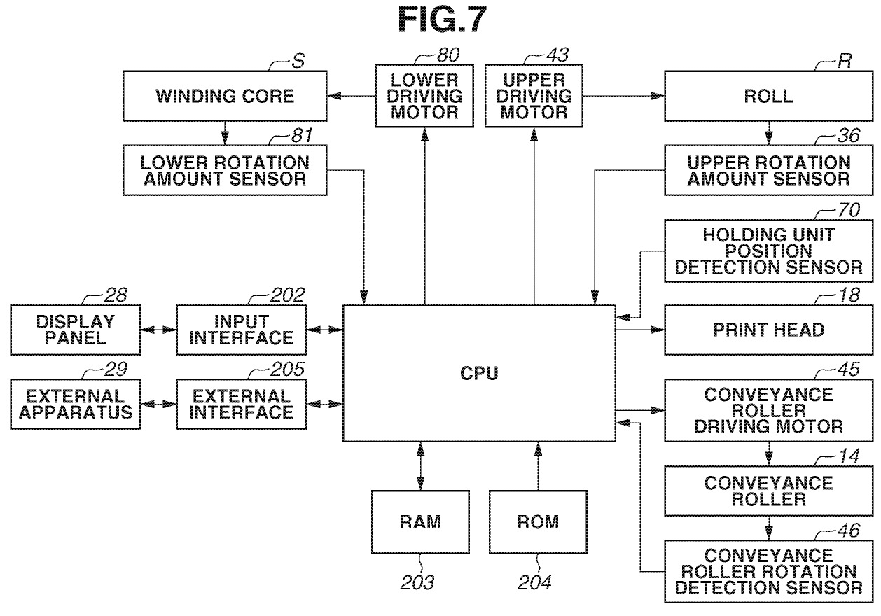

A sheet conveyance unit 300 includes a conveyance roller 14 and a nip roller 15 that is in pressure contact with the conveyance roller 14. The nip roller 15 pinches the sheet 1, and a conveyance roller driving motor 45 (see FIG. 7) drives the conveyance roller 14. The upper supply device 200 is used as the supply unit, and the roll R is set therein.

The sheet 1 drawn from the roll R is conveyed along a conveyance path of the sheet conveyance unit 300, and the printing unit 400 prints an image thereon. In the printing unit 400, a platen 17 comes into contact with a back surface of the sheet 1 to determine a Z direction position of the sheet 1, and an image is printed on the above-described sheet 1 by ejecting ink from a print head 18 using an ink-jet method. The print head 18 ejects ink from its ejection ports using an ejection energy generating element such as an electrothermal conversion element (heater), a piezoelectric element, and the like. The print head 18 is not limited to the ink-jet method, and a printing method of the printing unit 400 is not limited and may be, for example, a serial scan method, a full-line method, or the like. In the case of the serial scan method, an image is printed while performing a conveyance operation of the sheet 1 and scanning by the print head 18 in a direction intersecting the conveyance direction of the sheet 1. In the case of the full-line method, a long print head 18 extending in the direction intersecting the conveyance direction of the sheet 1 is used to print an image on the sheet 1 while continuously conveying the sheet 1. The present printing apparatus 100 illustrated in FIGS. 2A-2D winds the sheet 1 onto the winding core S without cutting it. In this case, in FIGS. 2A and 2B, the lower winding device 201 serves as the winding unit, and the winding core S is set therein. In a case where a length of the sheet 1 reaches the winding device 201, a leading edge of the sheet 1 is fixed to the winding core S, and the sheet 1 is wound. In FIGS. 2C and 2D, the upper winding device 200 serves as the winding unit, and the winding core S is set therein. The length of the sheet 1 reaches the winding device 200, the leading edge of the sheet 1 is fixed to the winding core S, and the sheet 1 is wound.

A cutter 20 is provided downstream of the printing unit 400 and can cut the sheet 1 on which an image is printed and discharged as described in FIG. 1 at an arbitrary position.

FIG. 7 is a block diagram illustrating a configuration example of a control system in the printing apparatus 100. The CPU 220 of the printing apparatus 100 controls each unit of the printing apparatus 100, including the display panel 28, the supply/winding devices 200 and 201, the sheet conveyance unit 300, and the printing unit 400 based on a control program stored in a read-only memory (ROM) 204. A type, a width, and various setting information of the sheet 1 are input to the CPU 220 from the display panel 28 via an input interface 202. The CPU 220 is also connected to various external apparatuses 29, including a host apparatus such as a personal computer or the like, via an external interface 205, transmits and receives various types of information such as print data to and from the external apparatus 29.

The CPU 220 writes and reads information from the display panel 28 and the external apparatus 29 to and from the RAM 203 and transmits a command to the print head 18 to execute printing on the sheet 1 based on desired print information. The CPU 220 can also control an upper driving motor 43 and a lower driving motor 80 to rotate the roll R and the winding core S forward and backward. The CPU 220 can control rotation while receiving rotational operation information from an upper rotation amount sensor 36 or a lower rotation amount sensor 81 that detect a rotation amount of the roll R or the winding core S. The CPU 220 can control the conveyance roller driving motor 45 to rotate the conveyance roller 14 forward and backward. A conveyance roller rotation detection sensor 46 detects a rotation amount of the conveyance roller 14, and the CPU 220 controls the conveyance roller driving motor 45 based on the detected information. Holding unit position detection sensors 70(1) and 70(2) (position detection units) are sensors for detecting that the holding unit 30(1) is set from a mounting position to a winding position.

There is no member for conveying the sheet 1 between the sheet conveyance unit 300 and the winding device 201 (winding unit), and a user performs an operation of attaching the sheet 1 to the winding device 201. Accordingly, a winding operation can be performed, and the printed sheet 1 can be stored in a rolled state.

### Sheet Supply Unit

As illustrated in FIGS. 2A and 2B, the upper supply device 200 and the lower winding device 201 are described as a sheet supply device (supply unit) and a sheet winding device (winding unit), respectively.

The sheet supply device (supply unit) is described with reference to FIGS. 2A-2D, 3, 4, 5A, and 5B.

The supply device 200 includes the rotatable holding unit 30(1) as a unit for supplying the sheet 1. In a case where the roll R is set in the holding unit 30(1), a user can set the roll R at a position where he or she can easily perform the operation by moving the holding unit 30(1) toward the front of the apparatus (in the Y direction) as illustrated in FIG. 2A. This position of the holding unit 30(1) is hereinbelow referred to as a roll mounting position. After the roll R is set in the holding unit 30(1), the holding unit 30(1) is moved to a rear side of the apparatus, and a sheet feeding operation is performed as illustrated in FIG. 2B. This position of the holding unit 30(1) serving as the supply unit is hereinbelow referred to as a sheet feeding position. As illustrated in FIGS. 3 and 4, the holding unit position detection sensor 70(1) (position detection unit) is configured as a sensor for detecting that the holding unit 30(1) is set from the roll mounting position to the sheet feeding position. Accordingly, it is possible to detect whether the supply device 200 is at the roll mounting position or the sheet feeding position.

An operation of mounting the roll R in the roll mounting position is described with reference to FIGS. 3, 4, 5A, and 5B. The holding unit 30(1) includes two reinforcing stays 31(1) and 32(1) extending in the sheet width direction. The holding unit 30(1) is mounted to the reinforcing stays 31(1) and 32(1) such that a home-side flange 33(1) is fixed and an away-side flange 34(1) is movable in the X direction. This is because printing on the sheet 1 is performed by conveying the sheet 1 based on the home side, and further, the away-side flange 34(1) is moved according to the size of the sheet being used to be able to hold the roll R from both sides. Further, a table 37(1) on which the roll R can be temporarily placed is provided between the home-side flange 33(1) and the away-side flange 34(1). The away-side flange 34(1) can be moved to an arbitrary position according to a width size of the roll R to be fed to place the roll R on the table 37(1). While lifting the roll R from the table 37(1) by hand, a user inserts a paper tube at the center of the roll R into a press-fitting portion 33(1)a of the home-side flange 33(1) and further inserts it into a press-fitting portion 34(1)a while moving the away-side flange 34(1). Accordingly, the roll R is rotatably held, and the mounting operation of the roll R is completed.

After the mounting is completed, if the holding unit 30(1) is rotated toward the rear of the apparatus (in the -Y direction) as illustrated in FIGS. 2B and 4, the roll R can be driven to rotate forward and backward by the upper driving motor 43 (see FIG. 7) via the press-fitting portion 33(1)a.

Next, a configuration for feeding the roll R to the printing unit 400 is described with reference to FIGS. 2A-2D, 3, and 4.

An arm member 4 is rotatably attached to a conveyance guide 12 about a rotation shaft 5. The arm member 4 is urged in a direction of an arrow A by a spring 3c, and driven rotating members 8 and 9 rotatably attached to a tip end of the arm member 4 are pressed against an outer periphery of the roll R from below in the direction of gravity. Further, a separation flapper 10 is rotatably attached above the arm member 4 about a rotation shaft 11. The separation flapper 10 is configured to rotate in a direction of an arrow B by its own weight and come into contact with and press against an outer peripheral surface of the roll R. If it is desirable to press the roll R even more strongly, an urging member such as a spring may be used to apply an urging force. A driven roller 10a is rotatably provided at a contact portion of the separation flapper 10 with the roll R in order to suppress an influence of a pressing force on the sheet 1. Further, a separation portion 10b at a tip end of the separation flapper 10 is formed to extend to a position as close to the surface of the roll R as possible.

The apparatus according to the present embodiment has an automatic loading function for the sheet 1. In the automatic loading function, in a case where a user sets the roll R in the apparatus, the apparatus starts detecting the leading edge of the sheet 1 while rotating the roll R in the direction opposite to that of sheet supply (feeding). The leading edge of the sheet 1 peels off from the outer peripheral surface of the rotating roll R by its own weight and approaches a sensor unit 6, so that a position of the leading edge of the sheet 1 is detected. Next, in a case where the apparatus rotates the roll R in a rotation direction of sheet supply, the leading edge of the sheet separated from the roll R is automatically fed out by the pressing force from the driven rotating members 8 and 9.

The sheet 1 is drawn out from the roll R by passing over the driven rotating members 8 and 9, guided on its lower surface by a guide surface on an upper side of the arm member 4, and then supplied through a supply conveyance path formed between the separation flapper 10 and the arm member 4. Further, the driven rotating members 8 and 9, the guide surface of the arm member 4, the driven roller 10a, and the separation flapper 10 are moved according to an outer diameter of the roll R, so that the sheet 1 can be reliably drawn out and conveyed from the roll R regardless of its outer diameter.

The conveyance guide 12 leads the sheet 1 to the printing unit 400 while guiding front and back surfaces of the sheet 1 drawn out from the supply device 200. The sheet 1 is pinched between the conveyance roller 14 located upstream of the printing unit 400 and the nip roller 15 that is pressed against the conveyance roller 14, and is conveyed to the printing unit 400 by the forward rotation of the conveyance roller 14, which is driven by the conveyance roller driving motor 45 (see FIG. 7) described below.

By using the automatic loading function according to the present embodiment in this way, the leading edge of the sheet 1 is automatically detected and fed to the printing unit 400 simply by setting the roll R, thereby eliminating time and effort for a user to find the leading edge of the sheet 1 and then manually feed it to the printing unit 400.

### Setting Sheet to Winding Unit

According to the present embodiment, the sheet 1 is set on the winding core S before a printing operation is started.

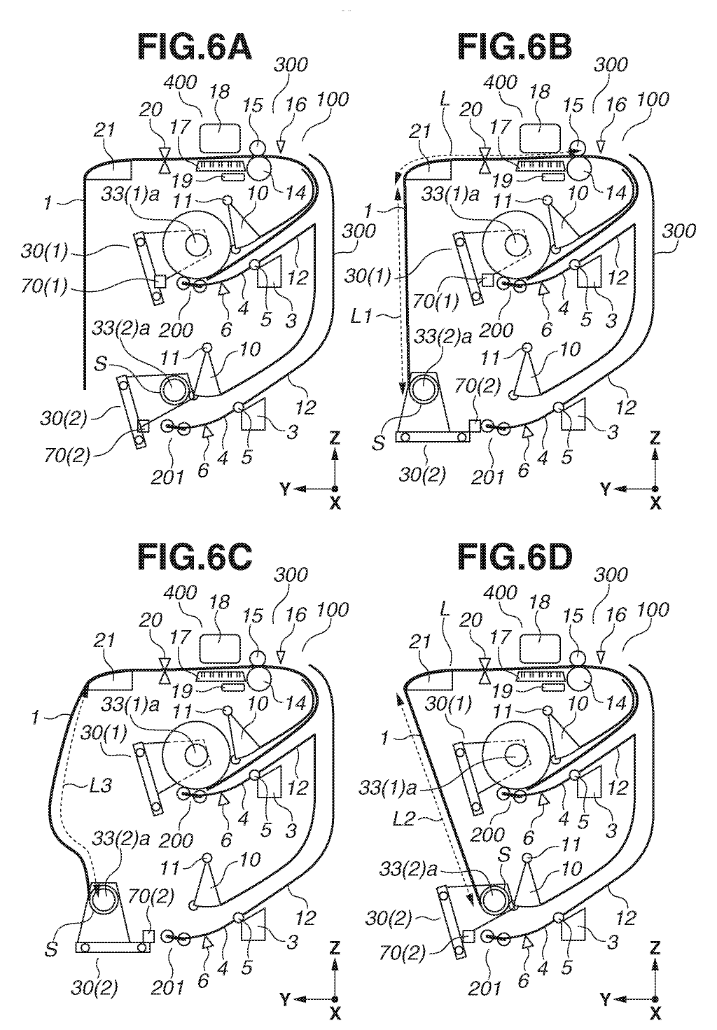

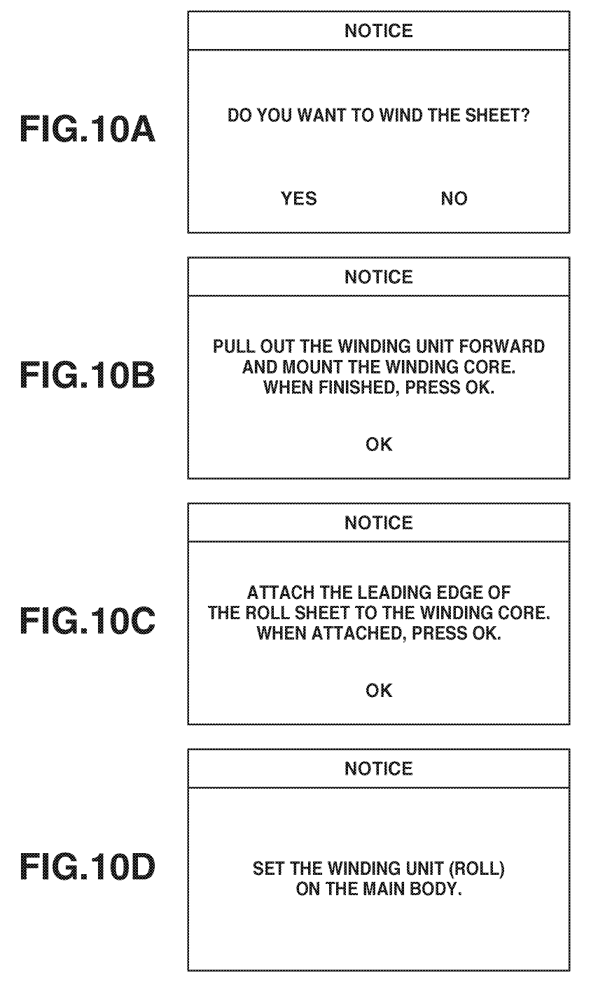

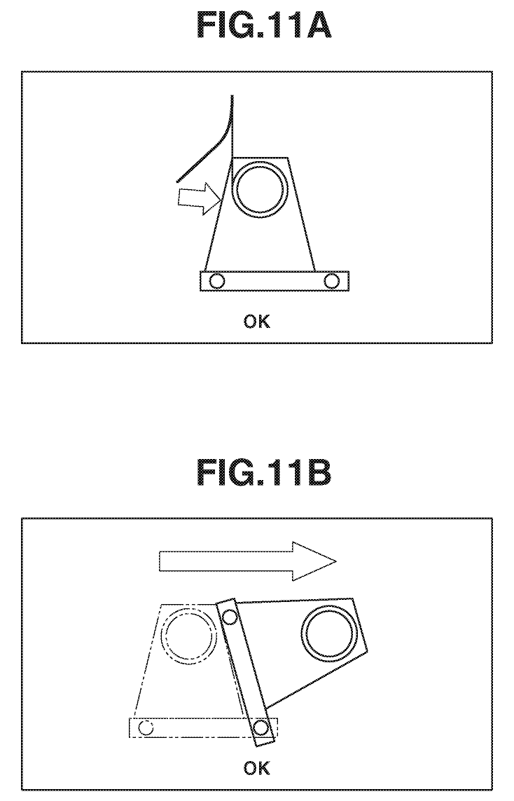

A setting operation of the sheet 1 using the winding device 201 disposed on the lower section as the winding unit for winding the sheet 1 is described with reference to FIGS. 6A-6D. FIGS. 10A-10D, 11A, and 11B illustrate examples of screens displayed on the display panel 28 during winding. The winding device 201 serving as the winding unit for winding the sheet includes the holding unit 30(2) that has a configuration similar to that of the supply device 200 serving as the supply unit.

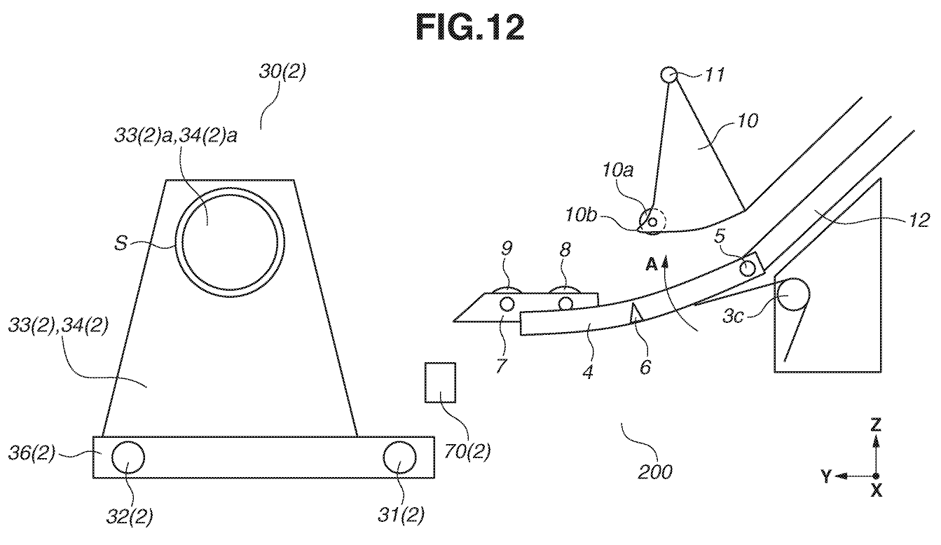

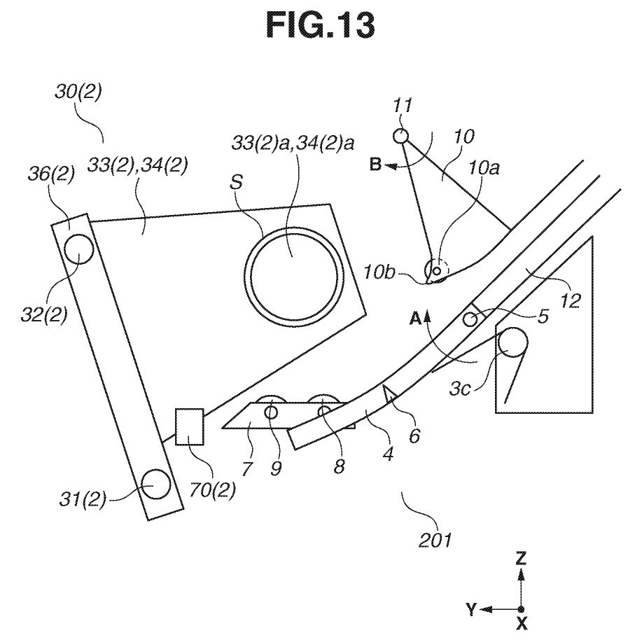

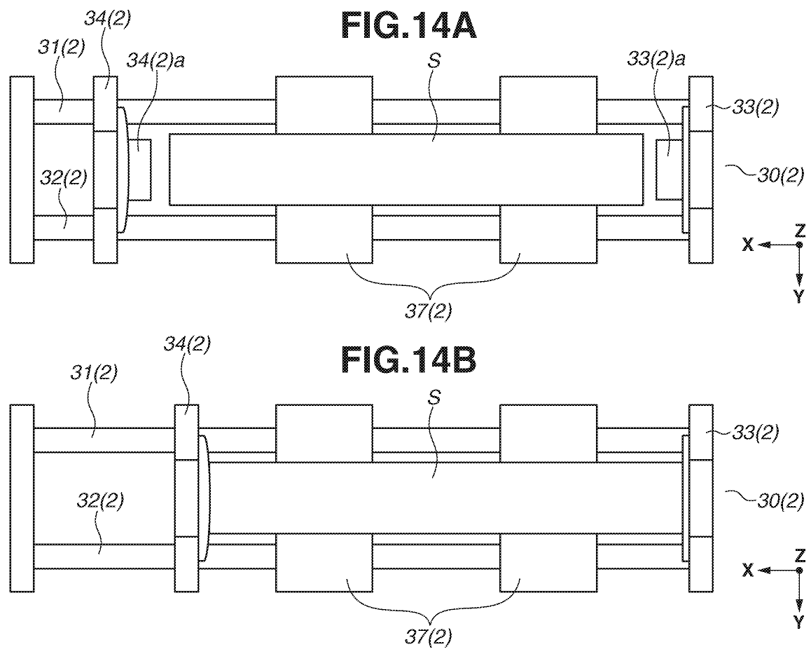

The winding device (winding unit) is described using the winding device 201 with reference to FIGS. 2A-2D, 12, 13, 14A, and 14B. FIGS. 12 and 13 are enlarged views of the winding device. FIGS. 14A and 14B are schematic top views of the winding device 201 as seen from above in the Z direction.

The winding device 201 includes the rotatable holding unit 30(2) as the winding unit for the sheet 1.

In a case where the winding core S is set in the holding unit 30(2), a user can set the winding core S at a position where he or she can easily perform the operation by moving the holding unit 30(2) toward the front of the apparatus (in the Y direction) as illustrated in FIG. 2A. This position of the holding unit 30(2) is hereinbelow referred to as a winding core mounting position. After the winding core S is set in the holding unit 30(2), the holding unit 30(2) is moved toward the rear of the apparatus, and a winding operation is performed as illustrated in FIG. 2B. This position of the holding unit 30(2) serving as the supply unit is hereinbelow referred to as a winding position. As illustrated in FIGS. 3 and 4, the holding unit position detection sensor 70(2) (position detection unit) is configured as a sensor for detecting that the holding unit 30(2) is set from the winding core mounting position to the winding position. Accordingly, it is possible to detect whether the winding device 201 is located at the winding core mounting position or the winding position.

An operation of mounting the winding core S in the winding core mounting position is described with reference to FIGS. 12, 13, 14A, and 14B. The holding unit 30(2) includes two reinforcing stays 31(2) and 32(2) extending in the sheet width direction and is mounted to the reinforcing stays 31(2) and 32(2) such that a home-side flange 33(2) is fixed and an away-side flange 34(2) is movable in the X direction. This is because printing on the sheet 1 is performed by conveying the sheet 1 based on the home side, and further, the away-side flange 34(2) is moved according to the size of the sheet being used to be able to hold the winding core S from both sides. Further, a table 37(2) on which the winding core S can be temporarily placed is provided between the home-side flange 33(2) and the away-side flange 34(2). The away-side flange 34(2) can be moved to an arbitrary position according to the width size of the winding core S to be fed to place the winding core S on the table 37(2). While lifting the winding core S from the table 37(2) by hand, a user inserts the paper tube at the center of the winding core S into a press-fitting portion 33(2)a of the home-side flange 33(2) and further inserts it into a press-fitting portion 34(2)a while moving the away-side flange 34(2). Accordingly, the winding core S is rotatably held, and the mounting operation of the winding core S is completed.

After the mounting is completed, in a case where the holding unit 30(2) is rotated toward the rear of the apparatus (in the -Y direction) as illustrated in FIGS. 2B and 4, the winding core S can be driven to rotate forward and backward by the lower driving motor 80 (see FIG. 7) via the press-fitting portion 33(2)a.

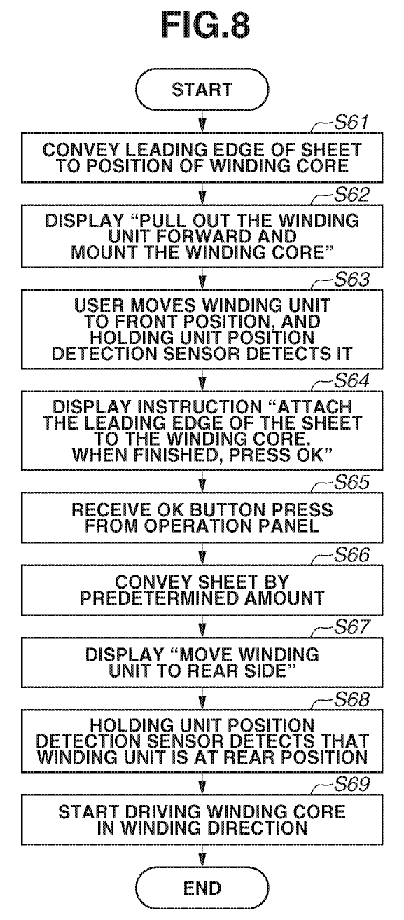

Next, control of the printing apparatus 100 associated with the setting operation of the sheet 1 in the winding device 201 as the winding unit is described with reference to FIGS. 6A-6D, 7, 8, 10A-10D, 11A, and 11B. FIGS. 6A-6D are schematic diagrams illustrating how the winding core S is set in the winding unit. FIG. 7 is a control block diagram of the printing apparatus 100. FIG. 8 is a control flowchart according to the present embodiment. FIGS. 10A-10D illustrate displays at the time of performing the winding operation. FIGS. 11A and 11B illustrate displays at the time of performing the winding operation.

The flow illustrated in FIG. 8 is started from a state where the sheet 1 is fed in advance. In a case where a user performs operations of mounting the winding core S to the winding device 201 and attaching the leading edge of the sheet 1 to the winding core S, the user rotates the holding unit 30(2) from the position in FIG. 6A to the position in the front of the apparatus in FIG. 6B. This movable configuration enables the user to perform the operation at a closer position. As a trigger for starting winding by the winding device 201, an instruction with a content illustrated in FIG. 10A is displayed on the display panel 28, and the winding is started in a case where the user selects "YES".

In step S61, the CPU 220 issues a command to the conveyance roller driving motor 45 to convey the sheet 1 by a predetermined amount until the leading edge of the sheet 1 reaches the position of the winding core S.

The predetermined amount at this time may be such that it does not interfere with the user rotating and moving the holding unit 30(2) forward, and accordingly, the sheet 1 is conveyed in advance by a distance L from the conveyance roller 14 to a paper discharge tray 21 and a distance L1 from the paper discharge tray 21 to the winding core S. In other words, the length of the sheet 1 from the nip roller 15 or the conveyance roller 14 is desirably about the distance L + L1. The sheet 1 is conveyed by rotating the nip roller 15. At this time, the conveyance roller rotation detection sensor 46 detects the rotation amount, and the nip roller 15 is rotated while adjusting the length.

In step S62, the CPU 220 displays instructions for mounting the winding core S, such as "Rotate the holding unit 30(2) forward" and "Mount the winding core", on the display panel 28 as illustrated in FIG. 10B.

In step S63, in a case where the user is prompted by the panel display and pulls out (rotates) the winding device 201 to the front position, the holding unit position detection sensor 70(2) (position detection unit) detects that the winding device 201 is pulled out to the front position and transmits this information to the CPU 220.

In step S64, the CPU 220 commands the display panel 28 to display a message (first display), such as "Attach the leading edge of the sheet to the winding core. When attached, press OK" prompting the user to fix the leading edge of the sheet to the winding core S as illustrated in FIG. 10C. The display at this time may be an illustration or animation, as illustrated in FIG. 11A, prompting the user to fix the leading edge of the sheet to the winding core S. Subsequently, the CPU 220 causes the display panel 28 to display a message prompting the user to operate it after completing the operation. Following the display, the user inserts the press-fitting portion 33(2)a into the winding core S to hold it,and then fixes the leading edge of the sheet 1 that has been conveyed in advance to the winding core S with tape.

In step S65, in a case where the user finishes attaching the leading edge of the sheet 1, he or she presses OK on the display panel 28 (fixing detection unit). Accordingly, the display panel 28 can detect that the leading edge of the sheet 1 is fixed to the winding core S. The information is transmitted from the display panel 28 to the CPU 220.

In step S66, after detecting that the leading edge of the sheet 1 is fixed to the winding core S, the CPU 220 commands the conveyance roller driving motor 45 to convey the sheet 1 by a predetermined amount. At this time, in a case where the distance L1 is shorter than a distance L2 from the paper discharge tray 21 to the winding core S as illustrated in FIG. 6D, the distance from the paper discharge tray 21 to the winding core S changes relatively. Thus, in a case where the holding unit 30(2) is rotated while the sheet is stretched at the position illustrated in FIG. 6B, the leading edge of the sheet 1 attached with tape peels off from the winding core S on the way to the position illustrated in FIG. 6D. Accordingly, the predetermined amount may be set to be greater than or equal to a distance difference (L2 - L1) between the winding core S and the paper discharge tray 21 caused by movement from the position in FIG. 6B to that in FIG. 6D. In order to prevent the leading edge of the sheet 1 from peeling off the winding core S, the sheet 1 is set in a stretched state at the position illustrated in FIG. 6B, and then is conveyed by the predetermined amount by the sheet conveyance unit 300 to form slack between the paper discharge tray 21 and the winding core S as illustrated in FIG. 6C. Subsequently, the holding unit 30(2) is rotated to the position illustrated in FIG. 6D. The conveyance length of the sheet 1, including a slack amount at this time, may satisfy condition L + L3 ≥ L + L2. More specifically, the conveyance amount of the sheet 1 conveyed from the sheet conveyance unit 300 can also be expressed as being greater than or equal to a difference between the following (1) and (2):
(1) a length of a conveyance path from the sheet conveyance unit 300 to the winding device 201 at the winding core mounting position; and
(2) a length of a conveyance path from the sheet conveyance unit 300 to the winding device 201 at the winding position.

Accordingly, this can prevent the leading edge of the sheet 1 from peeling off the winding core S due to the rotation of the holding unit 30(2). Here, the description is based on the distance from the paper discharge tray 21, but the distance from the sheet conveyance unit 300 to the paper discharge tray 21 is the same in both cases, so that it has the same meaning if it is described using the distance based on the sheet conveyance unit 300.

In step S67, in a case where the conveyance of the sheet 1 by the predetermined amount is completed, the CPU 220 causes the display panel 28 to display a message (second display), as illustrated in FIG. 10D, prompting the user to move the winding device 201 from the winding core mounting position to the winding position. At this time, an illustration as illustrated in FIG. 11B or an animation (not illustrated) may be displayed.

In step S68, in a case where the user is prompted by the panel display and rotates the winding device 201 to the rear position, the holding unit position detection sensor 70(2) (position detection unit) detects the operation and transmits the information to the CPU 220. Specifically, the holding unit 30(2) is rotated from the position illustrated in FIG. 6B to the rear of the apparatus (the -Y direction) illustrated in FIG. 6D. The winding core S can be driven to rotate by the lower driving motor 80 (see FIG. 7) serving as a drive unit via the press-fitting portion 33(2)a, and the sheet 1 that is fed out in conjunction with the printing operation is wound around the winding core S.

In step S69, the CPU 220 issues a command to the lower driving motor 80 connected to the holding unit 30(2) of the winding device 201 to rotate the winding core S to wind the slackened sheet of the roll R thereon.

Subsequently, the user starts the setting of the printing operation, and the printed sheet is wound by the winding device 201 in accordance with the printing operation.

In this way, the display panel 28 displays the message prompting the user to attach the leading edge of the sheet 1 to the winding core S and then to move the winding device 201 from a first position to a second position, thereby assisting the winding operation. According to the present embodiment, the predetermined conveyance amount in step S61 is set to the distance L + L1, but it can also be the distance L + L2. In this case, it becomes more difficult for the user to pull out the holding unit 30(2) from the main body. On the other hand, since there is no need to perform the processing in steps S65 and S66, the operation time can be reduced. Further, the present configuration is described such that the sheet 1 is stretched due to movement between the winding core mounting position and the winding position. However, in a case where the winding device 201 is configured such that the length of the sheet 1 resulting from the movement from the position in FIG. 6B to the position in FIG. 6D remains the same or slackens, step S66 may be omitted, and the process may proceed to step S67.

According to the present embodiment, the winding unit is described as the winding device 201 (lower section). However, even if the winding unit is the winding device 200 (upper section), the present embodiment can be applied using the conveyance amounts corresponding to the distances L1, L2, and L3 in a case where the winding unit is in the upper section.

According to the present embodiment, the winding device 201 is configured to rotate between the winding core mounting position and the winding position, but it may also be configured to move horizontally and linearly with respect to the main body (not illustrated).

### Second Embodiment

According to the above-described first embodiment, the operation of setting the sheet 1 in the winding core S before the start of the printing operation is described, but the sheet 1 may also be set in the winding core S during the printing operation, and this configuration is described in a second embodiment. Since the basic apparatus configuration is the same, the description thereof is omitted, and differences from the first embodiment are described.

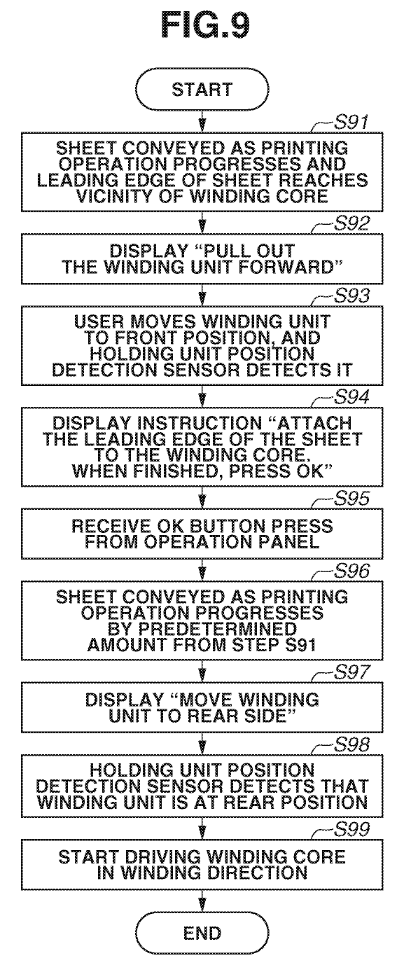

The present embodiment is described with reference to a control flow illustrated in FIG. 9.

In step S91, in the printing apparatus 100 according to the present embodiment, the sheet 1 is conveyed downstream while being printed in the printing unit 400, and the leading edge of the sheet 1 reaches the vicinity of the winding core S during printing.

In step S92, at this timing, the CPU 220 commands the display panel 28 to display a message "Move the winding device 201 forward (to the winding core mounting position)" to prompt a user to perform the operation following the panel display.

The subsequent steps S93 to S95 are the same as steps S63 to S65 in FIG. 8, and thus the descriptions thereof are omitted.

In step S96, the sheet 1 is gradually conveyed downstream as the printing operation progresses, and a predetermined amount of conveyance is performed from step S91.

In step S97, after the conveyance of the predetermined amount is completed, the CPU 220 commands the display panel 28 to display a message "Move the winding device 201 to the rear (to the winding position)" to prompt the user to perform the operation.

The subsequent steps S98 and S99 are the same as steps S68 and S69 in FIG. 8, and thus the descriptions thereof are omitted.

In a case where the operation is performed while printing in this way, printing starts from the leading edge of the sheet 1, so that it can be expected to reduce paper waste.

The present disclosure can also be realized by processing of supplying a program for implementing one or more functions of the above-described embodiments to a system or an apparatus via a network or a storage medium and having one or more processors in a computer of the system or the apparatus read and execute the program. The present disclosure can also be realized by a circuit (e.g., an application specific integrated circuit (ASIC)) that implements one or more functions.

According to each of the embodiments, it is possible to provide a control apparatus, a printing apparatus, a control method, and a program that enable operation from a desired operation apparatus in a state where a plurality of operation apparatuses are connected.

While the present disclosure has been described above with reference to the embodiments, it is to be understood that the present disclosure is not limited to these embodiments, and various modifications and changes can be made within the scope of the gist of the present disclosure.

According to the present disclosure, operations from attaching a leading edge of a sheet to winding it can be appropriately performed.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of priority from Japanese Patent Application No. 2025-025040, filed Feb. 19, 2025, which is hereby incorporated by reference herein in its entirety.

What is claimed is:

1. A printing apparatus comprising:
a conveyance unit configured to convey a sheet;
a printing unit configured to print an image on the sheet conveyed by the conveyance unit;
a winding unit configured to move between a first position where a user fixes a leading edge of the sheet and a second position where the sheet is wound, downstream of the printing unit in a sheet conveyance direction;
a display unit configured to display a first display prompting the user to fix the leading edge of the sheet to the winding unit and a second display prompting the user to move the winding unit from the first position to the second position; and
a fixing detection unit configured to detect that the user fixes the leading edge of the sheet,
wherein the display unit displays the second display in a case where the sheet is conveyed by a predetermined amount from the conveyance unit after detection by the fixing detection unit.

2. The printing apparatus according to claim 1, wherein the winding unit includes a holding unit configured to hold a winding core for fixing the leading edge of the sheet and a drive unit configured to rotate the holding unit.

3. The printing apparatus according to claim 1, wherein the winding unit rotates between the first position and the second position.

4. The printing apparatus according to claim 1, wherein the first display is displayed after the sheet is conveyed from the conveyance unit to the winding unit at the first position.

5. The printing apparatus according to claim 1, wherein the predetermined amount is greater than or equal to a difference between a length of a conveyance path from the conveyance unit to the winding unit at the first position and a length of a conveyance path from the conveyance unit to the winding unit at the second position.

6. The printing apparatus according to claim 5, wherein there is no member for conveying the sheet between the conveyance unit and the winding unit.

7. The printing apparatus according to claim 1, further comprising a position detection unit configured to detect that the winding unit is at the second position,
wherein, in a case where the position detection unit detects that the winding unit is at the second position, the winding unit starts winding.

8. The printing apparatus according to claim 1, wherein the fixing detection unit performs detection in a case where a user operates the display unit.

9. The printing apparatus according to claim 1, wherein the printing unit includes a print head and adopts an ink-jet method for ejecting ink from the print head.
